(19) United States
(12) Patent Application Publication
(10) Pub. No.: US 2002/0008506 A1
(43) Pub. Date: Jan. 24, 2002

(54) ELECTRIC POWER MEASURING METHOD, SYSTEM USING THE SAME AND COMPUTER-READABLE MEDIUM

(76) Inventors: JUICHI NAKADA, Tokyo (JP); SATOSHI KOIZUMI, Tokyo (JP)

Correspondence Address: LOWE HAUPTMAN GOPSTEIN, GILMAN & BERNER LLP, SUITE 310, 1700 DIAGONAL ROAD, ALEXANDRIA, VA, 22314

(21) Appl. No.: 09/435,364

(22) Filed: Nov. 8, 1999

(30) Foreign Application Priority Data
Nov. 11, 1998 (JP) 336566/1998
May 10, 1999 (JP) 284131/1999

(51) Int. Cl. G01R 19/18; G01R 19/22

(52) U.S. Cl. 324/120

(57) ABSTRACT

An electric power measuring system and method of simple configuration capable of measuring electric power in correspondence to an arbitrary frequency are provided. The QPSK signal is inputted to the spectrum analyzer. The frequency converter converts the QPSK signal into the IF signal. The A/D converter 16 converts the inputted IF signal into the digital data after the band pass filter removes an aliasing component contained in the IF signal. In the electric power calculating device, FIR filters perform a band limiting process, wherein the digital data is passed through the predetermined receiving filter, and extracting process of extracting an in-phase component I or an orthogonal component Q. The square operation devices square I or Q. The adder 25 adds I² to Q². Therefore, the electric power is calculated.

### BACKGROUND OF THE INVENTION

1. Field of the Invention

The present invention relates to measuring the electric power of a radio communication device in a spectrum analyzer or the like and also relates to displaying the results of the measurement.

2. Description of the Related Art

In a mobile communication system such as a portable telephone, the performance of the system is evaluated using an error rate of data obtained by demodulating a transmitted signal on a receiver side. According to this evaluation method there is measured a signal to noise ratio (SN ratio) in the case where the data demodulated on the receiver side is at a predetermined error rate (say 1%). Therefore, both signal and noise are inputted to the receiver.

Generally, the demodulation processing in a receiver is carried out for a signal which has passed through a receiving filter provided in the interior of the receiver. As the receiving filter there is used a filter which has been designed for each communication system in conformity with the frequency band width used in communication or a filter adapted to perform a band limitation almost equal to the frequency band width.

Consequently, the SN ratio which determines an error rate of a mobile communication system depends on the power ratio of the signal and noise passing through the receiving filter or on the power ratio of the signal and noise contained in the frequency band width used in communication. Therefore, to obtain a signal-noise power ratio it is necessary to accurately measure the electric power of the signal which has passed through the receiving filter or that of the signal contained in the communication band concerned. As methods for measuring electric power accurately several methods are known, for example, a method using a power meter and a method of measuring electric power in a zero span mode with use of a spectrum analyzer.

With a power meter, it is possible to measure all of the electric powers in a wide frequency band, but it is impossible to measure the electric power of a signal in a narrow communication band (say 30 kHz to 5 MHz). Thus, it is impossible to apply this method to the quality evaluation of the above communication system.

In a zero span mode of a spectrum analyzer, it is possible to extract a signal present in a predetermined resolving power band width and measure the electric power thereof, and a Gaussian filter is usually employed for extracting a signal present in a predetermined resolving power band width. The Gaussian filter is an analog filter constituted by an analog element and the frequency band which passes the filter is fixed, so a plurality of the Gaussian filters number is required to be provided to match the communication band to be measured. Besides, passing characteristics are not accurate due to variations in the quality of components used. Moreover, for accurately measuring electric power of communication devices using filters other than the Gaussian filter, it is necessary that various other filters than the Gaussian filter be provided in advance. Therefore, the circuit configuration becomes very complicated.

Further, an appropriate method for displaying measured electric power on a display screen has not been available heretofore. For example, according to a certain oscilloscope, a graph showing changes of amplitude with time and a histogram showing the degree of the amplitude are displayed in the same display screen. However, with the oscilloscope, it is impossible to measure electric power. In the case of measuring electric power using a spectrum analyzer or the like, instantaneous values are merely displayed or changes with time can merely be observed, and it is not easy to grasp an entire tendency of the measured electric power values.

The present invention has been accomplished in view of the above-mentioned points and it is an object of the invention to provide an electric power measuring system and method of a simple configuration capable of measuring electric power in correspondence to an arbitrary frequency band, as well as a recording medium which stores an electric power measuring program. It is another object of the present invention to provide an electric power measurement results display system and method capable of easily grasping an entire tendency, as well as a recording medium which stores an electric power measurement result display program.

### SUMMARY OF THE INVENTION

According to the invention defined in claim 1 there is provided an electric power measuring system including a digital filtering means for performing predetermined band limiting process and a predetermined signal mixing process simultaneously for an input signal, and an electric power calculating means for calculating electric power values of the input signal on the basis of output data provided from the digital filter.

In this invention, to solve the above-mentioned problems, a band limiting process and a mixing process of a predetermined signal are performed simultaneously for an input signal with use of a digital filter, and on the basis of the results obtained there are obtained electric power values of the input signal by the electric power calculating means. Therefore, if the characteristics of a band pass filter included in a device to be measured for electric power are needed to be changed, all that is required is to merely change the filter coefficient of the digital filter. Thus, it is not necessary to provide a plurality of band limiting filters of different characteristics, that is, a simple configuration permits the measurement of the electric power in correspondence to an arbitrary frequency band.

According to the invention defined in claim 2 there is provided, in combination with the invention of claim 1, an electric power measuring system wherein the input signal is an orthogonal modulation signal, the digital filtering means includes a first finite impulse response filtering means where a value is set as a tap coefficient, the value being obtained by multiplying an impulse response waveform of a band pass filter obtained in a device to be measured by a sine waveform of a frequency equal to the frequency of an intermediate-frequency signal converted from the input signal, and a second impulse response filtering means where a value is set as a tap coefficient, the value being obtained by multiplying the impulse response waveform by a waveform which is 90 degrees out of phase with the sine waveform, and the electric power calculating means has a first square operation means for squaring an output value of the first finite impulse response filter, a second square operation means for squaring an output value of the second finite impulse response filter, and an addition means for adding output data of the first and second square operation means.

Preferably, in the case where the input signal is an orthogonal modulation signal, the digital filter is constituted by first and second finite impulse response filters for each of which a value is set as a tap coefficient, the value being obtained by multiplying an impulse response waveform of a band pass filter by a sine waveform or by a waveform which is 90 degrees out of phase with the sine waveform, and the electric power calculating means is constituted by first and second square operation means and addition means. The first and second square operation means square data provided from the first and second digital filter. And the addition means adds output data provided from the first and second square operation means. Since a value obtained by multiplying an impulse response waveform of a band pass filter included in a device to be measured by a sine waveform of a frequency equal to the frequency of an intermediate-frequency signal (or a waveform 90 degrees out of phase with the sine waveform) is set as a tap coefficient for each of the impulse response filters, the use of the finite impulse response filters permits simultaneous execution of the same band limiting process as in the use of a band pass filter and a process of extracting in-phase component or orthogonal component from the orthogonal modulation signal. Besides, in the case of measuring electric power of a to-be-measured device using a band pass filter of different characteristics, it is possible to cope with it by merely changing the tap coefficient set for each of the finite impulse response filters. Thus, it is not necessary to provide any extra circuits in advance.

According to the invention defined in claim 3 there is provided, in combination with the invention of claim 1, an electric power measuring system further including a display means for displaying a time transition graph of the electric power values calculated by the electric power calculating means and a histogram of electric power values in such a manner that both the graph and histogram are arranged side by side within a single display screen.

For displaying measured electric powers it is desirable to adopt a method wherein a time transition graph of measured electric power values and a histogram showing an occurrence frequency of electric power values measured within a predetermined time period is arranged side by side within a single display screen. By so arranging the two in a single display screen it becomes easier to grasp an entire tendency of measured electric power values as compared with the case where they are arranged each independently.

According to the invention defined in claim 4 there is provided an electric power measurement results display system for displaying the results of having measured electric power values of an input signal, including a display means for displaying a time transition graph of input signal electric values and a histogram of electric power values measured within a predetermined time period in such a manner that both the graph and histogram are arranged side by side within a single display screen.

By arranging the graph and histogram so they have a common axis (say an axis of ordinate) corresponding to electric power values, the measured values indicated by them are associated with each other, so that the work required to analyze the results of the electric power value measurement becomes easier.

According to the invention defined in claim 5, in combination with the invention defined in claim 4, the time transition graph and the histogram have a common axis corresponding to electric power values.

Particularly, the above display can be realized by once storing the measured data of electric power values, describing a time transition graph of electric values with use of the measured data thus stored, calculating an occurrence frequency of electric power values with use of the measured data thus stored and subsequently describing a histogram, and further by writing the described data in an area corresponding to one display screen of a Video RAM (VRAM).

According to the invention defined in claim 6, in combination with the invention of claim 4, the display means includes a data storage means for storing data obtained by measuring electric power values of the input signal, a time transition graph drawing means for drawing the time transition graph on the basis of the data stored in the data storage means, an occurrence frequency calculating means for calculating an occurrence frequency of electric power values within a predetermined time period on the basis of the data stored in the data storage means, a histogram drawing means for drawing the histogram on the basis of the occurrence frequency of electric power values calculated by the occurrence frequency calculating means, and a video RAM in which image data drawn respectively by the time transition graph describing means and the histogram describing means are stored so as to be included within an area corresponding to one display screen.

The invention defined in claim 7 is constituted so as to include a digital filtering step that performs a predetermined band limiting process and a predetermined signal mixing process for an input signal and an electric power calculating step that calculates the electric power values of the input signal on the basis of the output data obtained in the digital filtering step.

According to the invention defined in claim 8, in combination with the invention of claim 7, the input signal is an orthogonal modulation signal, the digital filtering step includes a first finite impulse response filtering step in which a value is set as a tap coefficient, the value being obtained by multiplying an impulse response waveform of a band pass filter included in a device to be measured by a sine waveform equal to the frequency of an intermediate-frequency signal converted from the input signal, and a second finite impulse response filtering step in which a value is set as a tap coefficient, the value being obtained by multiplying the impulse response waveform by a waveform which is 90 degrees out of phase with the sine waveform, and the power calculating step includes a first square operation step of squaring an output value obtained in the first finite impulse response filtering step, a second square operation step of squaring an output value obtained in the second finite impulse response filtering step, and an addition step of adding output data obtained in the first and second square operation steps.

The invention defined in claim 9, in combination with the invention of claim 7, further includes a display step of displaying a time transition graph of electric power values calculated in the electric power calculating step and a histogram of electric power values in such a manner that both the graph and histogram are arranged side by side within a single display screen.

The invention defined in claim 10 is an electric power measurement result display method for displaying the results of having measured electric power values of an input signal, the system including a display step of displaying a time transition graph of electric power values of the input signal and a histogram of electric power values measured within a predetermined time period in such a manner that both the graph and histogram are arranged side by side within a single display screen.

According to the invention defined in claim 11, in combination with the invention of claim 10, the time transition graph and the histogram have a common axis corresponding to the electric power values.

According to the invention defined in claim 12, in combination with the invention of claim 10, the display step includes a data storing step of storing data obtained by measuring electric power values of the input signal, a time transition graph drawing step of drawing the time transition graph on the basis of the data stored in the data storing step, an occurrence frequency calculating step of calculating an occurrence frequency of electric power values within a predetermined time period on the basis of the data stored in the data storing step, a histogram drawing step of drawing the histogram on the basis of the occurrence frequency of electric power values calculated in the occurrence frequency calculating step, and an image data storing step of storing image data described respectively in the time transition describing step and the histogram describing step so as to be included in an area corresponding to one display screen.

The invention defined in claim 13 is a computer-readable medium including program instructions for correlating processing data and information by performing the steps of a digital filtering step of performing a predetermined band limiting process and a predetermined signal mixing process for an input signal and an electric power calculating step of calculating electric power values of the input signal on the basis of output data obtained in the digital filtering step.

The invention defined in claim 14, in combination with the invention of claim 13, is a computer-readable medium, wherein the input signal is an orthogonal modulation signal, the digital filtering step includes a first finite impulse response filtering step in which a value is set as a tap coefficient, the value is obtained by multiplying an impulse response waveform of a band limiting filter included in a device to be measured by a sine waveform of a frequency equal to the frequency of an intermediate-frequency signal converted from the input signal, and a second finite impulse response filtering step in which a value is set as a tap coefficient, the value being obtained by multiplying the impulse response waveform by a waveform which is 90 degrees out of phase with the sine waveform and the electric power calculating step includes a first square operation step of squaring an output value obtained in the first finite impulse response filtering step, a second square operation step of squaring an output value obtained in the second finite impulse response filtering step, and an addition step of adding output data obtained in the first and second square operation step.

The invention defined in claim 15, in combination with the invention of claim 13, provides a computer-readable medium including program instructions for correlating processing data and information by performing the step of a display step of displaying a time transition graph of electric power values calculated in the electric power calculating step and a histogram of electric power values in such a manner that both the graph and histogram are arranged side by side within a single display screen.

The invention defined in claim 16 is a computer-readable medium including program instructions for correlating processing data and information by performing the step of a display step of displaying a time transition graph of electric power values of the input signal and a histogram of electric power values measured within a predetermined time period in such a manner that both the graph and histogram are arranged side by side within a single display screen.

The invention defined in claim 17, in combination with the invention of claim 16, provides a computer-readable medium wherein the time transition graph and the histogram have a common axis corresponding to the electric power values.

The invention defined in claim 18, in combination with the invention of claim 16, provides a computer-readable medium wherein the display processing includes a data storing step of storing data obtained by measuring electric power values of the input signal, a time transition graph drawing step of drawing the time transition graph on the basis of the data stored in the data storing step, an occurrence frequency calculating step of calculating an occurrence frequency of electric power values within a predetermined time period on the basis of the data stored in the data storing step, a histogram drawing step of drawing the histogram on the basis of the occurrence frequency of electric power values calculated in the occurrence frequency calculating step, and an image data storing step of storing image data drawn respectively in the time transition graph drawing step and the histogram drawing process so as to be included in an area corresponding to one display screen.

According to the invention defined in claim 19 there is provided an electric power measuring system including a digital filter that performs predetermined band limiting process and a predetermined signal mixing process simultaneously for an input signal, and an electric power calculating device that calculates electric power values of the input signal on the basis of output data provided from the digital filter.

According to the invention defined in claim 20 there is provided, in combination with the invention of claim 19, an electric power measuring system wherein the input signal is an orthogonal modulation signal, the digital filter includes a first finite impulse response filter where a value is set as a tap coefficient, the value being obtained by multiplying an impulse response waveform of a band pass filter obtained in a device to be measured by a sine waveform of a frequency equal to the frequency of an intermediate-frequency signal converted from the input signal, and a second impulse response filter where a value is set as a tap coefficient, the value being obtained by multiplying the impulse response waveform by a waveform which is 90 degrees out of phase with the sine waveform, and the electric power calculating means has a first square operation device that squares the output value of the first finite impulse response filter, a second square operation device that squares the output value of the second finite impulse response filter, and an addition device that adds output data of the first and second square operation means.

According to the invention defined in claim 21 there is provided, in combination with the invention of claim 19, an electric power measuring system further including a display device that displays a time transition graph of the electric power values calculated by the electric power calculating means and a histogram of electric power values in such a manner that both graph and histogram are arranged side by side within a single display screen.

According to the invention defined in claim 22 there is provided an electric power measurement results display system for displaying the results of the measured electric power values of an input signal, the system including a display device that displays a time transition graph of input signal electric values and a histogram of electric power values measured within a predetermined time period in such a manner that both the graph and histogram are arranged side by side within a single display screen.

According to the invention defined in claim 23, in combination with the invention defined in claim 22, the time transition graph and the histogram have a common axis corresponding to electric power values.

According to the invention defined in claim 24, in combination with the invention of claim 22, the display device includes a data storage means which stores data obtained by measuring electric power values of the input signal, a time transition graph drawing device that draws the time transition graph on the basis of the data stored in the data storage means, an occurrence frequency calculating device that calculates an occurrence frequency of electric power values within a predetermined time period on the basis of the data stored in the data storage means, a histogram drawing device that draws the histogram on the basis of the occurrence frequency of electric power values calculated by the occurrence frequency calculating device, and a video RAM in which image data drawn respectively by the time transition graph drawing device and the histogram drawing device are stored so as to be included within an area corresponding to one display screen.

The nature, utility, and further features of this invention will be more clearly apparent from the following detailed description with respect to preferred embodiments of the invention when read in conjunction with the accompanying drawings briefly described below.

### BRIEF DESCRIPTION OF THE DRAWINGS

In the accompany drawings:

FIG. 1 is a diagram showing a partial configuration of a spectrum analyzer according to an embodiment of the present invention;

FIG. 2 is a diagram showing a detailed configuration of an FIR filter;

FIG. 3 is a diagram for explaining tap coefficients stored in n numbers of registers which are disposed within the FIR filter;

FIG. 4 is a diagram showing a detailed configuration of a display device illustrated in FIG. 1;

FIG. 5 is a diagram showing a display example of electric power measurement results;

FIG. 6 is a flow chart showing the operation of the spectrum analyzer;

FIG. 7 is a flow chart showing in what procedures both the band limiting process and the in-phase component I (or orthogonal component Q) extracting process are to be executed; and

FIG. 8 is a flow chart showing a detailed processing procedure for the display of electric power.

### DESCRIPTION OF THE PREFERRED EMBODIMENTS

A preferred embodiment according to the present invention will now be described below with reference to the accompanying drawings. It should be noted that the same reference numbers are used to denote the same elements.

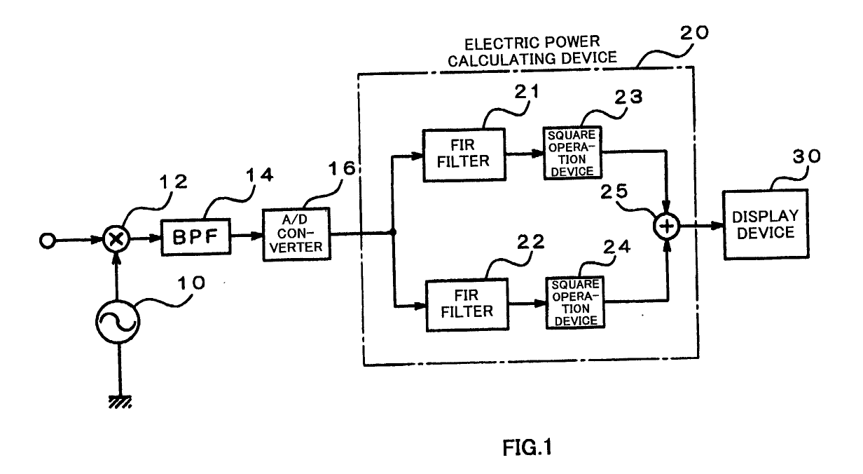

An embodiment of the present invention will be described hereunder with reference to the accompanying drawings. FIG. 1 is a diagram showing a partial configuration of a spectrum analyzer according to an embodiment of the present invention, in which a predetermined band limiting process is applied to an inputted QPSK modulation signal as an orthogonal modulation signal in the measurement of electric power.

The spectrum analyzer shown in FIG. 1 includes a local oscillator 10, a frequency converter 12, a band pass filter (BPF) 14, an analog-digital (A/D) converter 16, an electric power calculating device 20, and a display device 30.

The local oscillator 10 generates a predetermined local signal for use in frequency conversion. The frequency converter 12 mixes the local signal outputted from the local oscillator 10 with the inputted QPSK signal and then outputs an analog IF signal as the difference of the two. The frequency of the IF signal can be converted to digital data by an A/D converter 16 which is described hereinafter and is required to include the frequency band of the QPSK modulation signal. The band pass filter 14 performs a band limiting process for the IF signal outputted from the frequency converter 12 and removes an aliasing component contained in the IF signal. The A/D converter 16 converts the inputted IF signal into digital data for performing various arithmetic operations in the electric power calculating device 20, which is described hereinafter. The electric power calculating device 20 calculates the electric power of the QPSK modulation signal on the basis of the IF signal after conversion to digital data by the A/D converter 16. In this calculation of electric power, consideration is given to the characteristics of the predetermined receiving filter, and the electric power of the signal which passes through the receiving filter is calculated.

The electric power calculating device 20 includes two finite impulse response (FIR: Finite Impulse Response) filters 21 and 22, two square operation devices 23 and 24, and an adder 25. One FIR filter 21 performs the operation of extracting an in-phase component I by multiplication of the local signal which has been used in the orthogonal modulation through a Gaussian filter as a receiving filter having a predetermined passing band width, while the other FIR filter 22 performs an operation of extracting an orthogonal component Q by multiplication of a signal which is 90 degrees out of phase with the local signal used in the FIR filter 21. As to the details of the FIR filters 21 and 22, reference will be made thereto later.

The square operation device 23 performs an operation of squaring the in-phase component I of a signal which is outputted from the FIR filter 21 and which has passed through the receiving filter. Likewise, the square operation device 24 performs an operation of squaring the orthogonal component Q of a signal which is outputted from the other FIR filter 22 and which has passed through the receiving filter. The results (I², Q²) of these arithmetic operations are added by the adder 25 and an added value (I² +Q²) is outputted from the electric power calculating device 20 as an instantaneous value of electric power of the signal after passing through the receiving filter.

The display device 30 displays the electric power value of the QPSK modulation signal thus calculated by the electric power calculating device 20 on a display screen in a predetermined form. For example, the display device 30 displays the electric power value so that a graph showing a time transition of the calculated instantaneous electric power values and a histogram obtained by measuring the occurrence frequency of the instantaneous electric power values within a predetermined time period are included in the same display screen.

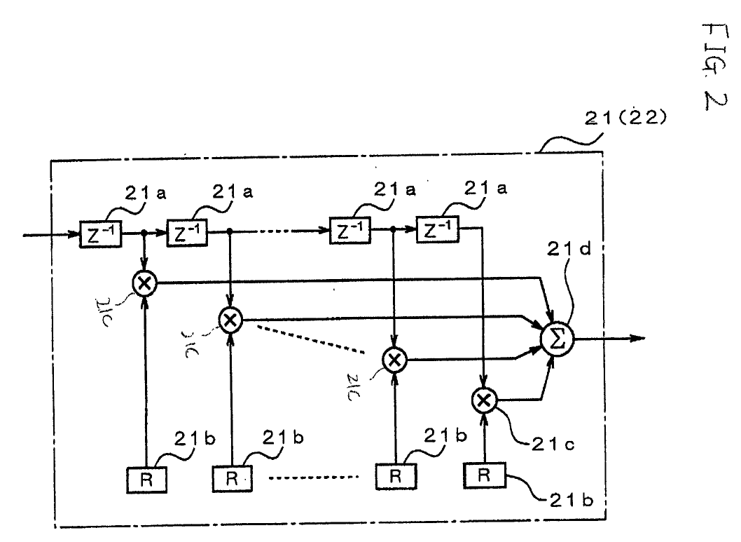

FIG. 2 is a diagram showing a detailed configuration of the FIR filter 21. As shown in the same figure, the FIR filter 21 comprises n number of delay elements (Z⁻¹) 21a, n number of registers (R) 21b, n number of multipliers 21c, and an adder 21d. The n number of delay elements 21a are connected in a cascade form so that data (instantaneous values of electric power) outputted from the electric power calculating device 20 are shifted in order from the initial-stage delay element 21a towards the delay elements 21a which follow. The n number of registers 21b are for storing tap coefficients of the FIR filter 21. Elements of a progression formed by discretely obtaining the product of the impulse response of the receiving filter and the local signal (sine wave) which is subjected to multiplication for obtaining the in-phase component I, are stored in the n number of registers 21b. The frequency of the local signal is set to the frequency of the IF signal. The n number of multipliers 21c multiply data held in and outputted from the n number of delay elements 21a respectively by the values of tap coefficients stored respectively in the n number of registers 21b. The n number of multiplication results are added by the adder 21d and the result of the addition is taken out as an output of the FIR filter 21.

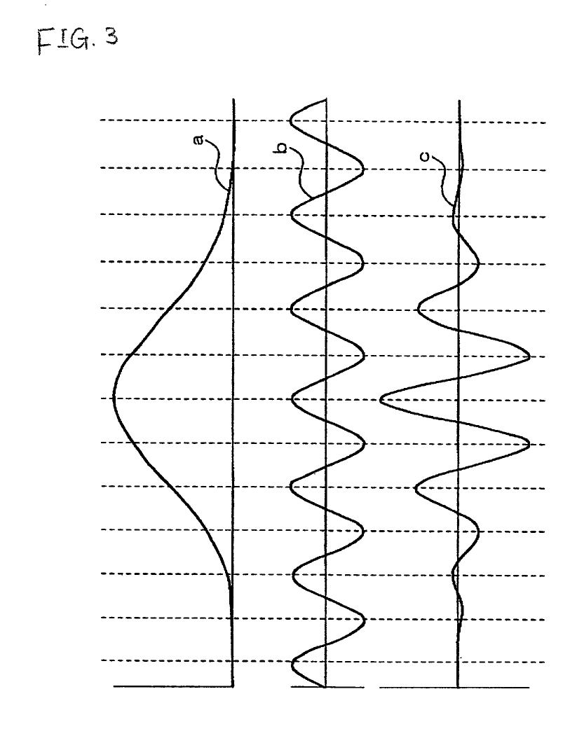

FIG. 3 is a diagram to explain the tap coefficients stored in the n number of registers 21b which are disposed within the FIR filter 21. In the same figure, a curved line, a, represents the waveform of impulse response of a Gaussian filter, a curved line, b, represents the waveform of the local signal which is represented in terms of a sine wave, and a curved line, c, represents a waveform which is determined as the product of the impulse response of the Gaussian filter represented by the curved line, a, and the sine waveform of the curved line, b.

In general, by setting an impulse response of a receiving filter as a tap coefficient of an FIR filter, it is possible to establish the characteristics of the receiving filter by the FIR filter. In the FIR filter 21 used in this embodiment, a value obtained by multiplying the waveform of impulse response of the receiving filter by a sine waveform is used as a tap coefficient. Therefore, both a band limiting process for the receiving filter and a local signal sine waveform mixing process are simultaneously performed for the input IF signal.

The FIR filter 22 has the same configuration as the configuration of the FIR filter 21, but is different in the contents of tap coefficients stored in the registers 21b. In the FIR filter 21 described above, a value obtained by multiplying the impulse response waveform of the receiving filter by the sine waveform of a local signal is used as a tap coefficient, while in the FIR filter 22 a value obtained by multiplying the impulse response waveform of the receiving filter by a signal waveform which is 90 degrees out of phase with the sine waveform of the local signal, is used as a tap coefficient.

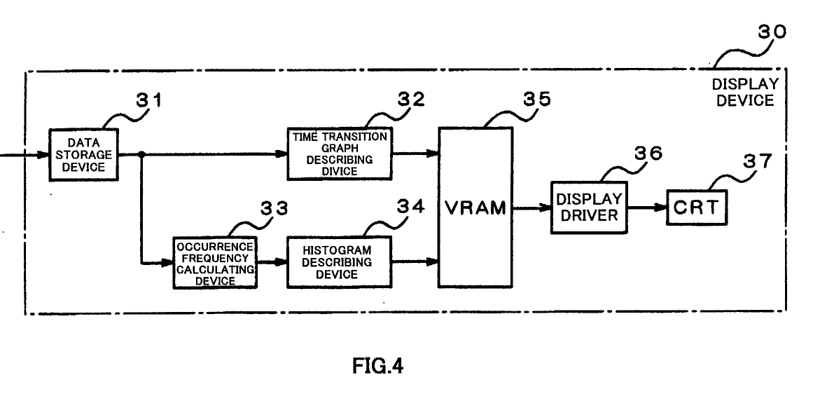

FIG. 4 shows a detailed configuration of the display device 30 illustrated in FIG. 1. As shown in FIG. 4, the display device 30 includes a data storage device 31, an occurrence frequency calculating device 33, a time transition graph drawing device 32, a histogram drawing device 34, a VRAM (video RAM) 35, a display driver 36, and a CRT (cathode-ray tube) 37.

Instantaneous value data of electric power calculated by the electric power calculating device 20 are inputted to the data storage device 31 at sampling intervals in the A/D converter 16. The data storage unit 31 stores the data successively in the order of input. The time transition graph drawing device 32 reads out in the order of storage of the data stored in the data storage device 31 and draws an image of a time transition graph of instantaneous electric power values in which time is plotted along the axis of abscissa and electric power values plotted along the axis of ordinate. The occurrence frequency calculating device 33 reads out data in a predetermined time period (say 25 μs) from the data storage device 31 and calculates a frequency distribution showing an occurrence frequency of each electric power value. The histogram drawing device 34 draws an image of an electric power value histogram in which instantaneous electric power values are read along the axis of ordinate and the occurrence frequencies of electric power values in the predetermined time period are read along the axis of abscissa. The time transition graph drawing device 32 and the histogram drawing device 34 store image data in an area corresponding to one display screen in the VRAM 35 in such a manner that the axis of ordinate corresponding to electric power values is common to both graph and histogram. The display driver 36 reads out in a scan direction the image data stored in the VRAM 35 and produces a video signal for display. A predetermined electric power measurement result image is displayed on the display screen of the CRT 37.

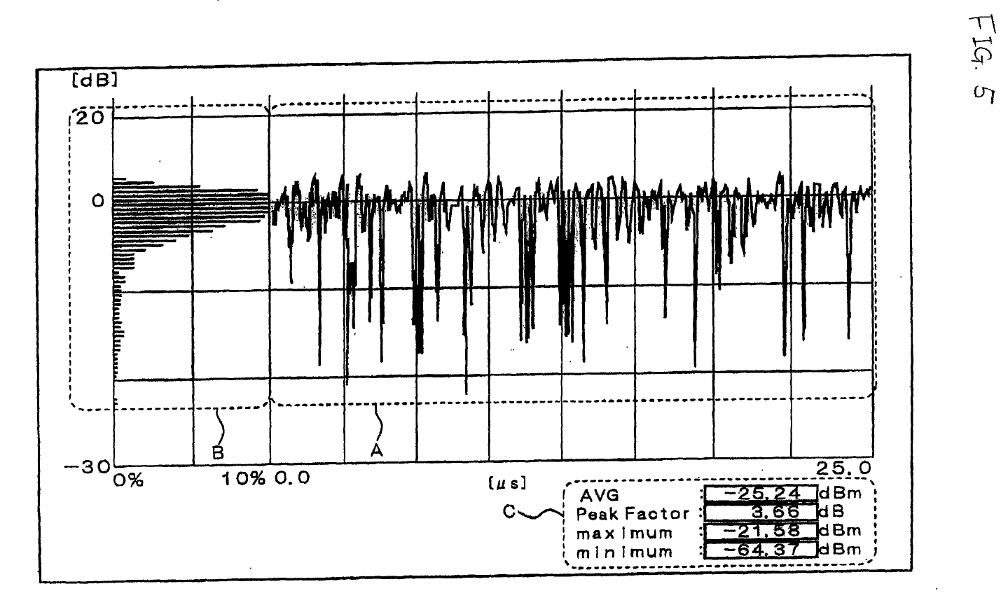

FIG. 5 is a diagram showing a display example of electric power measurement results. In the same figure, an area A is a display area of the time transition graph of instantaneous electric power values drawn by the time transition graph drawing device 32 in the display device 30, indicating in what manner instantaneous electric power values of the received signal changes with the lapse of time. For example, a reduced scale of display on the axis of ordinate is adjusted so that the average of electric power values included in this graph is 0 dB. An area B is a display area of the electric power value histogram drawn by the histogram drawing unit 34, indicating in what frequency there appear electric power values in a predetermined time period showing a time transition of instantaneous electric power values in area A.

Further, an area C is a display area of various data for use as reference data in the analysis of electric power measurement results. For example, “average value (AVG)”, “peak factor (Peak Factor)”, “maximum value (maximum)” and “minimum value (minimum)” are shown in the area C. The average value is an average value of electric powers (absolute values) in a predetermined time period. In both areas A and B the position corresponding to an output power value (relative value) of 0 dB indicated by the axis of ordinate corresponds to the average value in question. The peak factor is the difference between the average value of the electric power and the maximum electric power value. The maximum value and the minimum value are of the instantaneous electric power values in a predetermined time period corresponding to the area A.

As shown in FIG. 5, in both the time transition graph of the instantaneous electric power values shown in area A and the electric power value histogram shown in area B, the axes of ordinate represent electric power values, which corresponds to a common scale.

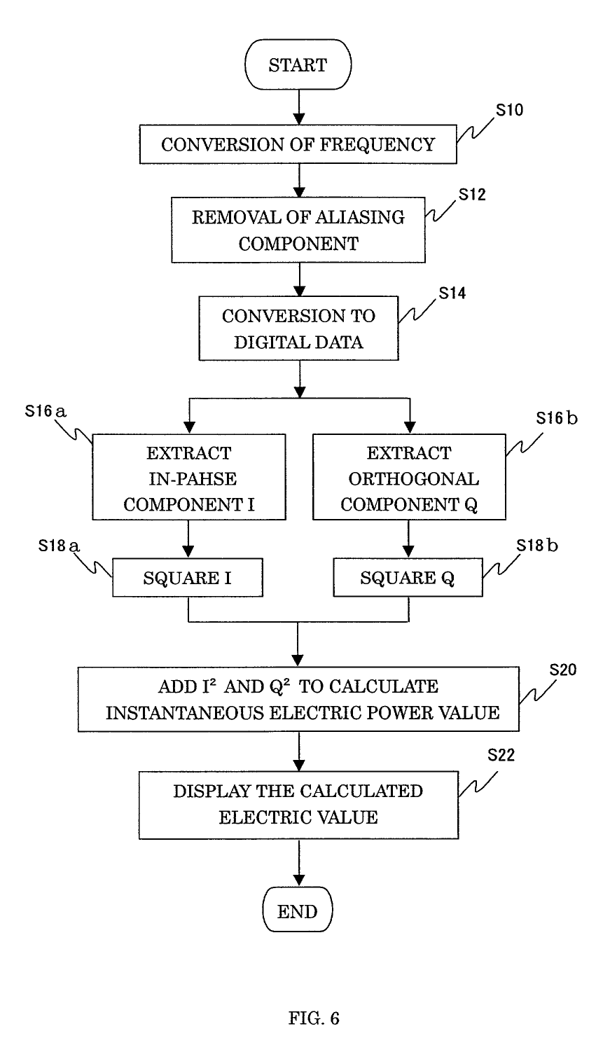

The spectrum analyzer of this embodiment has such a configuration and now a description will be given of its operation with reference to the flow chart of FIG. 6. Once a QPSK modulation signal to be analyzed is inputted to the spectrum analyzer of this embodiment, it is converted to an IF signal by the frequency converter 12 (S10). Aliasing component is removed from the IF signal by means of the band pass filter 14 (S12), which IF signal is then inputted to the A/D converter 16 for conversion to digital data (S14).

In the electric power calculating device 20, both a band limiting process involving passage through a predetermined receiving filter and an in-phase component I extracting process involving multiplication by a sine waveform are performed simultaneously by one FIR filter 21 (S16a), while by the other FIR filter 22 there are simultaneously performed both a band limiting process involving passage through a predetermined receiving filter and an orthogonal component Q extracting process involving multiplication by a waveform which is 90 degrees out of phase with the the sine waveform (S16b).

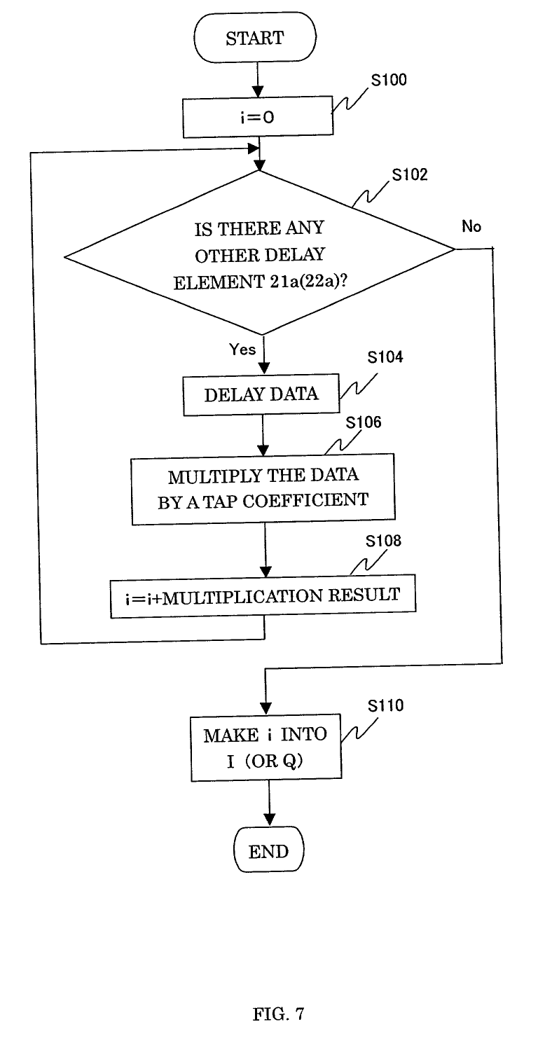

A processing procedure for the execution of both the band limiting process and the in-phase component I (or orthogonal component Q) extracting process will now be described with reference to the flow chart of FIG. 7. First, a variable, i, which indicates the in-phase component I (or orthogonal component Q) is initialized, that is, is set to zero (S100). Next, it is judged whether there is any other delay element 21a (22a) which has not delayed data yet (S102). If there is any other such delay data 21a (22a) (S102, Yes), a signal is delayed by that delay element 21a (S104). Then, the signal is multiplied by a tap coefficient stored in a register 21b by means of the multiplier 21c (S106). Next, the adder 21d adds the multiplication result obtained by the multiplier 21c to the variable, i, (S108). The processing flow then returns to the judgment of whether there is any other delay element 21a (22a) (S102). When all the delay elements 21a (22a) have delayed data (S102, No), the variable, i, is made into the in-phase component (or orthogonal component Q) (S110).

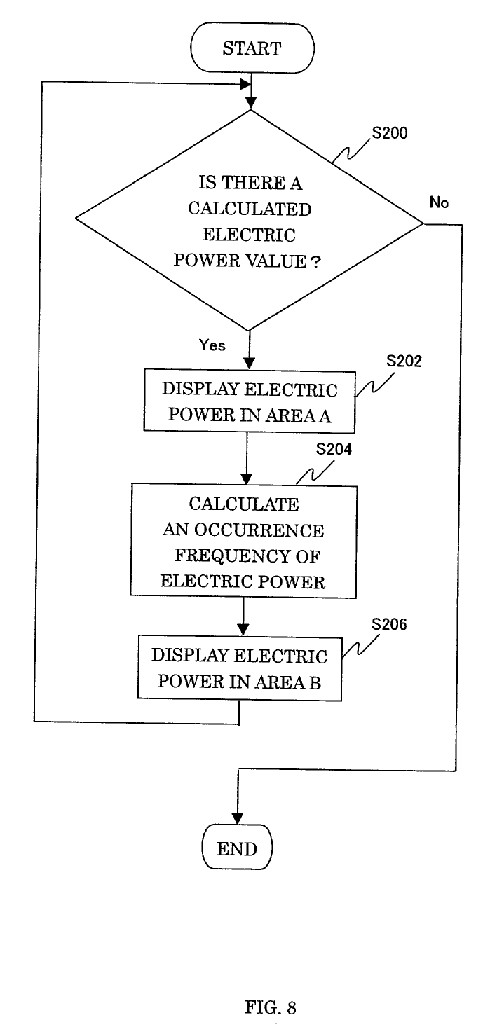

Turning back to FIG. 6, the in-phase component I is squared by the square operation unit 23 (S18a), the orthogonal component Q is squared by the square operation unit 24, and I² and Q²are added by the adder 25. The result of the addition (I²+Q²) is outputted as an instantaneous value of electric power after passage through the receiving filter (S20). Then, the display section 30 displays the calculated electric power (S22). As to the details of electric power display, it will be described with reference to the flow chart of FIG. 8.

In the display device 30, the instantaneous electric power values calculated by the electric power calculating device 20 are stored in the order of input into the data storage device 31. Unless there is any calculated instantaneous electric power values in the data storage unit 31 (S200, No), the display is ended. On the other hand, if the answer is affirmative (S200, Yes), a time transition graph of instantaneous electric power values is described in area A (see FIG. 5) by the time transition graph drawing device 32 (S202). Next, an occurrence frequency (frequency distribution) of instantaneous electric power values is calculated by the occurrence frequency calculating unit 33 (S204). Calculation of the occurrence frequency involves calculating a proportion of a certain frequency relative to an overall number of datum, for example, the electric power in the range of 1 to 2 dB accounting for 10% of the whole. Further, a histogram which represents such an occurrence frequency is drawn by the histogram drawing device 34 (S206). Plotting data corresponding to this time transition graph and histogram are stored in the VRAM 35 so that both the graph and histogram are arranged side by side within a single display screen while allowing electric power values to be associated with a common axis of ordinate. The displayed image shown in FIG. 5 appears on the CRT 37 by the display driver 36.

Thus, in measuring the electric power of only a predetermined band component from within a received signal, the spectrum analyzer of this embodiment performs the band limiting process with use of the FIR filters 21 and 22. Therefore, by changing the contents of the registers 21b included in the FIR registers 21 and 22 to change tap coefficients, characteristics such as the passing band width can be set as desired and the measurement of electric power matching various receiving filters can be done without changing the configuration, thus making it possible to simplify the circuit configuration. Particularly, even in the case of using various other filters than Gaussian filters as receiving filters, all that is required is only to determine an impulse response of the characteristic of the receiving filter used and to set the tap coefficients for the FIR filters 21 and 22. Thus, the measurement of electric power for various receiving filters can be done without changing the configuration.

Besides, as a tap coefficient which is stored in each of the registers 21b in the FIR filters 21 and 22 there is set a value obtained by multiplying an impulse response waveform of a Gaussian filter by a sine waveform having the same frequency as that of an IF signal or by a waveform which is 90 degrees out of phase with the sine waveform, thus permitting the omission of a local signal mixing process which has heretofore been necessary for extracting both in-phase component I and orthogonal component Q from the received QPSK signal. That is, it is no longer required to provide an oscillator that generates such a local signal and a mixer that performs an analog multiplication of signals. Moreover, it becomes possible to simplify the circuit configuration.

Further, in the spectrum analyzer of the above embodiment, the results of the electric power measurement are displayed in such a manner that the time transition graph of instantaneous electric power values and the histogram of electric power values are arranged side by side within a single display screen, and thus it becomes easier to grasp an overall tendency of the electric power measurement results. Particularly, since the axis of ordinate in the time transition graph and that in the histogram are both common to each other, the two measurement results can be displayed in association with each other, thus facilitating the analysis of the measurement results. Additionally, since data related to measured electric power values such as average value, maximum value, minimum value and peak factor are included in the same display screen, the analysis of the measurement results becomes still easier.

The present invention is not limited to the above embodiment, but various modifications may be made within the gist of the present invention. For example, although in the above embodiment a QPSK modulation signal is used as the inputted orthogonal modulation signal, there may be used an offset QPSK modulation signal or a signal modulated by any other modulation method than QPSK. For the measurement of electric power, which is band limited, using a filter other than Gaussian filter, there may be adopted a method wherein an impulse response of the filter is calculated or read from a table or the like and the impulse response is multiplied by a sine waveform or a waveform which is 90 degrees out of phase with the sine waveform to establish a tap coefficient for each of the FIR filters 21 and 22. Although in the above embodiment the band pass filter 14 is used for removing such an unnecessary component as aliasing component from the IF signal outputted from the frequency converter 12, there may be used a low pass filter for the same purpose.

The following method may also be adopted for implementing the spectrum analyzer of the above embodiment.

In a computer equipped with a CPU, a hard disk, and a media (e.g. floppy disk and CD-ROM) reader, the media reader is allowed to read a medium which stores a program for implementing the foregoing various portions, and the program thus read is installed in the hard disk. Even by such a method it is possible to implement the spectrum analyzer.

In the electric power measuring system according to the present invention, as set forth above, after an input signal is converted to an intermediate-frequency signal, both band limiting process and predetermined frequency mixing process are performed simultaneously using a digital filter, and on the basis of the results obtained there is calculated an electric power value of the input signal with use of an electric power calculating means. When the characteristics of a band pass filter included in the system for electric power are to be changed, this can be done by merely changing the contents of the filter coefficient of the digital filter, so that it is not necessary to provide a plurality of band limiting filters of different characteristics and hence a simple configuration suffices to measure electric power values in an arbitrary frequency band.

For displaying the measured electric power it is desirable to adopt a method wherein a time transition graph of measured electric power values and a histogram showing an occurrence frequency of electric power values measured in a predetermined time period are arranged side by side within a single display screen. By arranging the two side by side in a single display screen, it becomes easier to grasp the overall tendency of the measured electric power values as compared with the case where the two are arranged independently. Further, by arranging such graph and histogram so as to have a common axis corresponding to electric power values, the measured values represented by them are associated with each other and therefore the electric power value analyzing work becomes easier.

The present invention may be embodied in other preferred forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. An electric power measuring system comprising:
a digital filtering means for performing a predetermined band limiting process and a predetermined signal mixing process simultaneously for an input signal; and
an electric power calculating means for calculating electric power values of said input signal on the basis of output data of said digital filter.

2. An electric power measuring system according to claim 1, wherein:
said input signal is an orthogonal modulation signal;
said digital filtering means comprises a first finite impulse response filtering means where a value is set as a tap coefficient, said value being obtained by multiplying an impulse response waveform of a band pass filter contained in a device to be measured by a sine waveform of a frequency equal to the frequency of an intermediate-frequency signal converted from said input signal, and a second impulse response filtering means where a value is set as a tap coefficient, said value being obtained by multiplying said impulse response waveform by a waveform which is 90 degrees out of phase with said sine waveform; and
said electric power calculating means has a first square operation means for squaring an output value of said first finite impulse response filter, a second square operation means for squaring an output value of said second finite impulse response filter, and an addition means for adding output data provided from said first and second square operation means.

3. An electric power measuring system according to claim 1, further comprising a display means for displaying a time transition graph of the electric power values calculated by said electric power calculating means and a histogram of electric power values in such a manner that both said graph and histogram are arranged side by side within a single display screen.

4. An electric power measurement results display system for displaying the results of having measured electric power values of an input signal, comprising:
a display means for displaying a time transition graph of electric power values of an input signal and a histogram of electric power values measured within a predetermined time period in such a manner that both said graph and histogram are arranged side by side within a single display screen.

5. An electric power measurement results display system according to claim 4, wherein said time transition graph and said histogram have a common axis corresponding to the electric power values.

6. An electric power measurement results display system according to claim 4, wherein said display means comprises:
a data storage means for storing data obtained by measuring electric power values of said input signal;
a time transition graph drawing means for drawing said time transition graph on the basis of the data stored in said data storage means;
an occurrence frequency calculating means for calculating the occurrence frequency of electric power values within a predetermined time period on the basis of the data stored in said data storage means;
a histogram drawing means for drawing said histogram on the basis of the occurrence frequency of electric power values calculated by said occurrence frequency calculating means; and
a video RAM in which image data drawn respectively by said time transition graph describing means and said histogram describing means are stored so as to be included within an area corresponding to one display screen.

7. An electric power measuring method comprising:
a digital filtering step of performing a predetermined band limiting process and a predetermined signal mixing process for an input signal; and
an electric power calculating step of calculating electric power values of said input signal on the basis of output data obtained in said digital filtering step.

8. An electric power measuring method according to claim 7, wherein:
said input signal is an orthogonal modulation signal;
said digital filtering step comprises a first finite impulse response filtering step where a value is set as a tap coefficient, said value being obtained by multiplying an impulse response waveform of a band pass filter included in a device to be measured by a sine waveform of a frequency equal to the frequency of an intermediate-frequency signal converted from said input signal, and a second finite impulse response filtering step where a value is set as a tap coefficient, said value being obtained by multiplying said impulse response waveform by a waveform which is 90 degrees out of phase with said sine waveform; and
said power calculating step comprises a first square operation step of squaring an output value obtained in said first finite impulse response filtering step, a second square operation step of squaring an output value obtained in said second finite impulse response filtering step, and an addition step of adding output data obtained in said first and second square operation steps.

9. An electric power measuring method according to claim 7, further comprising a display step of displaying a time transition graph of electric power values calculated in said electric power calculating step and a histogram of electric power values in such a manner that both said graph and histogram are arranged side by side within a single display screen.

10. An electric power measurement result display method for displaying the results of having measured electric power values of an input signal, comprising a display step of displaying a time transition graph of electric power values of the input signal and a histogram of electric power values measured within a predetermined time period in such a manner that both said graph and histogram are arranged side by side within a single display screen.

11. An electric power measurement results display method according to claim 10, wherein said time transition graph and said histogram have a common axis corresponding to the electric power value.

12. An electric power measurement results display method according to claim 10, wherein said display step comprises:
a data storing step of storing data obtained by measuring electric power values of said input signal;
a time transition graph drawing step of drawing said time transition graph on the basis of the data stored in said data storing step;
an occurrence frequency calculating step of calculating an occurrence frequency of electric power values within a predetermined time period on the basis of the data stored in said data storing step;
a histogram drawing step of drawing said histogram on the basis of the occurrence frequency of electric power values calculated in said occurrence frequency calculating step; and
an image data storing step of storing image data described respectively in said time transition graph describing step and said histogram describing step so as to be included in an area corresponding to one display screen.

13. A computer-readable medium comprising program instructions for correlating processing data and information by performing the steps of:
a digital filtering step of performing a predetermined band limiting process and a predetermined signal mixing process for an input signal; and
an electric power calculating step of calculating electric power values of said input signal on the basis of output data obtained in said digital filtering step.

14. A computer-readable medium according to claim 13, wherein:
said input signal is an orthogonal modulation signal;
said digital filtering step comprises a first finite impulse response filtering step in which a value is set as a tap coefficient, said value being obtained by multiplying an impulse response waveform of a band limiting filter included in a device to be measured by a sine waveform of a frequency equal to the frequency of an intermediate-frequency signal converted from said input signal, and a second finite impulse response filtering step in which a value is set as a tap coefficient, said value being obtained by multiplying said impulse response waveform by a waveform which is 90 degrees out of phase with said sine waveform; and
said electric power calculating step comprises a first square operation step of squaring an output value obtained in said first finite impulse response filtering step, a second square operation step of squaring an output value obtained in said second finite impulse response filtering step, and an addition step of adding output data obtained in said first and second square operation step.

15. A computer-readable medium according to claim 13, comprising program instructions for correlating processing data and information by performing the step of:
a display step of displaying a time transition graph of electric power values calculated in said electric power calculating step and a histogram of electric power values in such a manner that both said graph and histogram are arranged side by side within a single display screen.

16. A computer-readable medium comprising program instructions for correlating processing data and information by performing the step of:
a display step of displaying a time transition graph of electric power values of the input signal and a histogram of electric power values measured within a predetermined time period in such a manner that both said graph and histogram are arranged side by side within a single display screen.

17. A computer-readable medium according to claim 16, wherein said time transition graph and said histogram have a common axis corresponding to the electric power values.

18. A computer-readable medium according to claim 16, wherein said display processing comprises:
a data storing step of storing data obtained by measuring electric power values of said input signal;
a time transition graph drawing step of drawing said time transition graph on the basis of the data stored in said data storing step;
an occurrence frequency calculating step of calculating an occurrence frequency of electric power values within a predetermined time period on the basis of the data stored in said data storing step;
a histogram drawing step of drawing said histogram on the basis of the occurrence frequency of electric power values calculated in said occurrence frequency calculating step; and
an image data storing step of storing image data described respectively in said time transition graph describing step and said histogram describing step so as to be included in an area corresponding to one display screen.

19. An electric power measuring system comprising:
a digital filter that simultaneously performs a predetermined band limiting process and a predetermined signal mixing process with respect to an input signal; and
an electric power calculating device that calculates electric power values of said input signal on the basis of the output data of said digital filter.

20. An electric power measuring system according to claim 19, wherein:
said input signal is an orthogonal modulation signal;
said digital filter comprises a first finite impulse response filter where a value is set as a tap coefficient, said value being obtained by multiplying an impulse response waveform of a band pass filter contained in a device to be measured by a sine waveform of a frequency equal to the frequency of an intermediate-frequency signal converted from said input signal, and a second impulse response filter where a value is set as a tap coefficient, said value being obtained by multiplying said impulse response waveform by a waveform that is 90 degrees out of phase with said sine waveform; and
said electric power calculating device contains a first square operation device that squares an output value of said first finite impulse response filter, a second square operation device that squares an output value of said second finite impulse response filter, and an addition device that adds output data provided from said first and second square operation device.

21. An electric power measuring system according to claim 19, further comprising a display device that displays a time transition graph of the electric power values calculated by said electric power calculating device and a histogram of electric power values both in such a manner that both said graph and histogram are arranged side by side within a single display screen.

22. An electric power measurement results display system for displaying the results of the measured electric power values of an input signal, comprising:
a display device that displays a time transition graph of electric power values of an input signal and a histogram of electric power values measured within a predetermined time period in such a manner that both said graph and histogram are arranged side by side within a single display screen.

23. An electric power measurement results display system according to claim 22, wherein said time transition graph and said histogram have a common axis corresponding to the electric power values.

24. An electric power measurement results display system according to claim 22, wherein said display device comprises:
a data storage device that stores data obtained by measuring electric power values of said input signal;
a time transition graph drawing device that draws said time transition graph on the basis of the data stored in said data storage device;
an occurrence frequency calculating device that calculates an occurrence frequency of electric power values within a predetermined time period on the basis of the data stored in said data storage device;
a histogram drawing device that draws said histogram on the basis of the occurrence frequency of electric power values calculated by said occurrence frequency calculating device; and
a video RAM in that image data drawn respectively by said time transition graph describing device and said histogram describing device are stored so as to be included within an area corresponding to one display screen.
